(19) United States
(12) Patent Application Publication
(10) Pub. No.: US 2023/0391055 A1
(43) Pub. Date: Dec. 7, 2023

(54) COMPOSITE WAFER AND MANUFACTURING METHOD THEREFOR

(71) Applicant: Shin-Etsu Chemical Co., Ltd., Tokyo (JP)

(72) Inventor: Shoji AKIYAMA, Gunma (JP)

(21) Appl. No.: 18/450,433

(22) Filed: Aug. 16, 2023

Related U.S. Application Data
(63) Continuation of application No. PCT/JP2022/004850, filed on Feb. 8, 2022.

(30) Foreign Application Priority Data
Feb. 19, 2021 (JP) 2021-025484

(51) Int. Cl. B32B 18/00; B32B 17/06; B32B 9/00; B32B 37/24; B32B 38/00; C04B 37/04

(52) U.S. Cl. CPC B32B 18/00; C04B 2237/062; B32B 9/005; B32B 37/24; B32B 38/0008; C04B 37/045; C04B 2237/341; C04B 2237/30; B32B 2255/20; B32B 2315/08; B32B 2315/02; B32B 2037/246; B32B 2313/00; C04B 2237/555; B32B 17/06

(57) ABSTRACT

Provided are a manufacturing method for a composite wafer and a composite wafer obtained by using the manufacturing method, the manufacturing method including: preparing a first substrate in which a first layer of any one of oxides, oxynitrides, and nitrides is disposed on one surface; preparing a second substrate in which a second layer of any one of oxides, oxynitrides, and nitrides is disposed on one surface; forming a silicon layer on a surface of one of the first layer or the second layer; activating, with plasma, a surface of at least one of the silicon layer or another of the first layer or the second layer; and bonding the first substrate and the second substrate.

The contents of the following patent application(s) are incorporated herein by reference:
NO. 2021-025484 filed in JP on Feb. 19, 2021
NO. PCT/JP2022/004850 filed in WO on Feb. 8, 2022

### BACKGROUND

### 1. Technical Field

The present invention relates to a composite wafer and a manufacturing method therefor.

### 2. Related Art

As a method for bonding two wafers, there is a method in which a surface of the wafer to be bonded is treated with plasma, washed as necessary, bonded, and subjected to low-temperature heat treatment (see Patent Document 1).

### CITATION LIST

### Patent Document

Patent Document 1: Japanese patent No. 6396852

### Technical Problem

However, in this plasma activation method, combining strength in a low temperature range greatly varies depending on surface material of the wafer to be bonded. In particular, when oxides and nitrides are bonded to each other, there is a problem that bonding strength at a cryogenic temperature is weak, and a joining interface is peeled off due to warpage or the like before sufficient strength is obtained.

### BRIEF DESCRIPTION OF THE DRAWINGS

FIG. 1 illustrates a relationship between a substance on a surface to be bonded and joining strength.

FIG. 2 schematically illustrates a cross-sectional view of a composite wafer 10 according to the present embodiment.

FIG. 3 schematically illustrates each stage of a manufacturing method of the composite wafer 10.

FIG. 4 illustrates an optical microscope image of glass (transparent) and LT bonded with amorphous silicon of 160 nm interposed therebetween.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

The present inventors first investigated which substance has high joining strength by plasma surface activation.

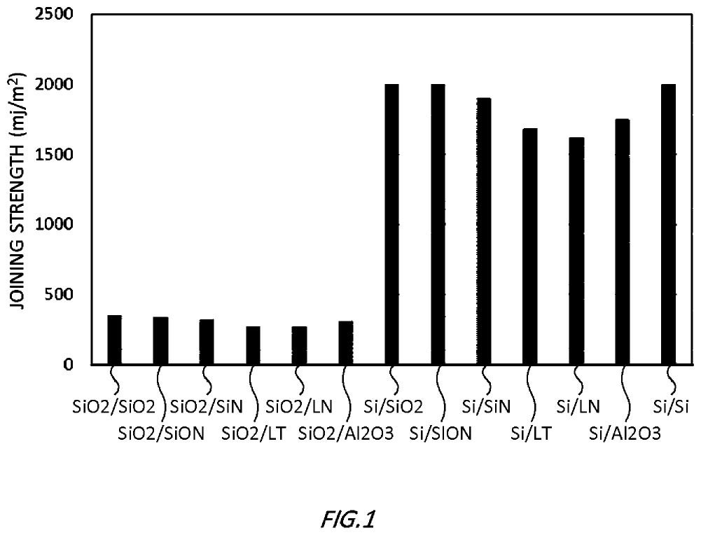

FIG. 1 illustrates a relationship between a substance on a surface to be bonded and joining strength. Activation was performed in a nitrogen atmosphere for about 30 seconds. After bonding, treatment was performed at 100° C. for 24 hours. The joining strength was measured by a blade insertion method (examples of the blade insertion method include “Semiconductor Wafer Bonding-Science and Technology-” Q.-Y. Tong and U. Gosele et al., p. 25-28, John Wiley & Sons, Inc. 1999).

From this result, it can be seen that the joining strength between oxides is relatively weak. It can be seen that the joining strength increases when Si is added. However, in joining of Si/Si, the joining strength after heat treatment of 90° C. was high, but the joining was peeled off when the treatment of a temperature (250° C.) higher than that was performed. This is considered to be because the moisture confined in the joining interface had no escape and destroyed the joining at the time of vaporization.

With Si and other substances, the treatment at 250° C. could be completed without any problem. Therefore, it can be seen that in order to obtain high joining strength at a low temperature, high joining strength can be obtained by joining Si to any one of oxides, oxynitrides, and nitrides. However, it is not always possible to use a silicon wafer as a bonded wafer.

In this regard, in the present embodiment, when one wafer surface is any one of oxides, oxynitrides, and nitrides, a thin Si film is formed on the other wafer surface. As a result, the joining of Si/oxides (or oxynitrides, nitrides) is realized.

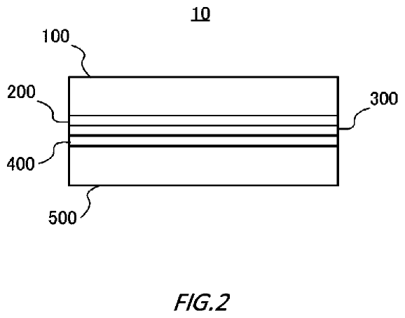

FIG. 2 schematically illustrates a cross-sectional view of a composite wafer 10 according to the present embodiment. The composite wafer 10 includes a first substrate 100, a first layer 200 disposed on one surface of the first substrate 100, a second substrate 500, a second layer 400 disposed on one surface of the second substrate 500, and a silicon layer 300 disposed between the first layer 200 and the second layer 400.

The first substrate 100 is, for example, any one of silicon, glass, alumina, sapphire, lithium tantalate, and lithium niobate. The first substrate 100 has a thickness of, for example, several hundred μm.

The first layer 200 is, for example, any one of oxides, oxynitrides, and nitrides. The first layer 200 is preferably any one of SiO₂, SiON, and SiN. The first layer 200 has a thickness of several tens nm to several μm.

The second substrate 500 is also, for example, any one of silicon, glass, alumina, sapphire, lithium tantalate, and lithium niobate. The material of the second substrate 500 may be the same as or different from the material of the first substrate 100. The second substrate 500 has a thickness of, for example, several hundred μm.

The second layer 400 is, for example, any one of oxides, oxynitrides, and nitrides. The second layer 400 is preferably any one of SiO₂, SiON, and SiN. The material of the second layer 400 may be the same as or different from the material of the first layer 200. The second layer 400 has a thickness of several tens nm to several μm.

The silicon layer 300 is what is formed on one or both of the first layer 200 and the second layer 400 and left between the first layer 200 and the second layer 400 after bonding. The silicon layer 300 is preferably amorphous silicon.

The silicon layer 300 is preferably 2 nm or more and 250 nm or less. In order to ensure high transparency in optical applications or the like and to obtain low dielectric loss in high-frequency applications, it is preferable that the silicon layer is thin. Note that, when it is not necessary to obtain high transparency and low dielectric loss, the silicon layer 300 may have a thickness of 250 nm or more. On the other hand, when the silicon layer is excessively thin, the silicon layer easily oxidizes and changes into SiO₂, and thus the silicon layer preferably has a thickness of several atomic layers or more.

A concentration of argon contained in the silicon layer 300 is preferably 1.5% atomic or less. In addition, the surface concentration of iron, chromium, and nickel contained in the silicon layer is preferably 5.0e10 atoms/cm 2 or less. These can be realized by bonding with plasma activation to be described later.

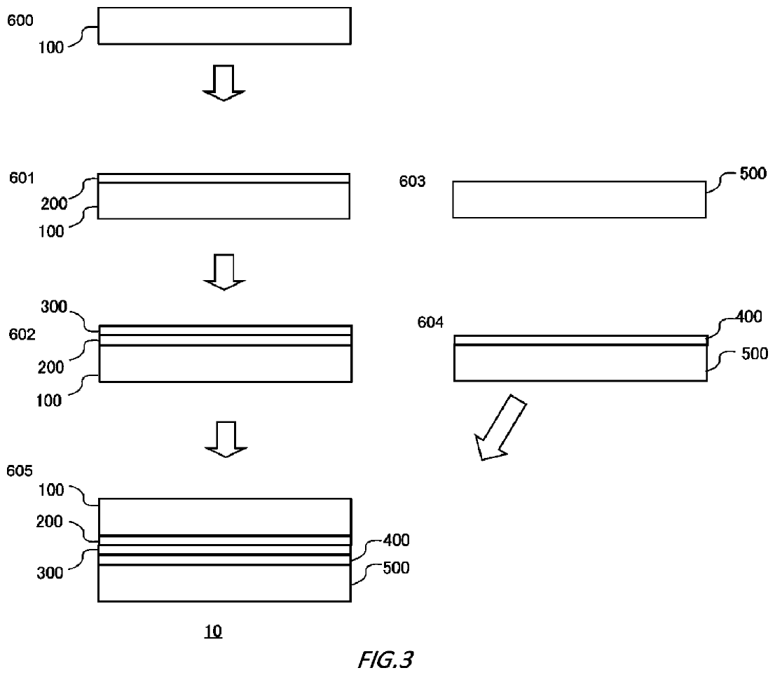

FIG. 3 schematically illustrates each stage of a manufacturing method of the composite wafer 10.

600 of FIG. 3 illustrates a stage of preparing the first substrate 100. The example of FIG. 3 shows a state of the first substrate 100 before the first layer 200 is provided. The first substrate 100 is obtained by cutting out an LT single crystal ingot formed by a pulling method into a plate shape having a thickness of several hundred μm, for example.

601 of FIG. 3 illustrates a stage of forming the first layer 200 on one surface of the first substrate 100. When the first substrate 100 is LT, the first layer 200 is, for example, SiO₂. The first layer 200 is polished after film formation to be flattened.

602 of FIG. 3 illustrates a stage of forming the silicon layer 300 on the bonding surface side of the first layer 200, that is, on the side opposite to the first substrate 100. The silicon layer 300 is amorphous silicon film formed by, for example, a physical vapor deposition (PVD) method. Instead of the PVD method, a chemical vapor deposition method (CVD) method may be used.

603 of FIG. 3 illustrates a stage of preparing the second substrate 500. The example of FIG. 3 shows a state of the second substrate 500 before the second layer 400 is provided. The second substrate 500 is obtained by cutting out a silicon single crystal ingot formed by a pulling method into a plate shape having a thickness of several hundred μm, for example.

604 of FIG. 3 illustrates a stage of forming the second layer 400 on one surface of the second substrate 500. When the second substrate 500 is silicon, the second layer 400 is, for example, SiO₂. The second layer 400 is, for example, a thermal oxide film obtained by oxidizing the second substrate 500 at around 1000° C.

605 of FIG. 3 illustrates a stage of bonding the first substrate 100 and the second substrate 500. Before bonding the first substrate 100 and the second substrate 500, at least one of the surfaces to be bonded is activated with plasma. That is, in the present embodiment, at least one of the surface of the silicon layer 300 or the surface of the second layer 400 is activated. The atmosphere of activation with plasma preferably contains at least one of nitrogen, oxygen, a gas mixture of oxygen and nitrogen, or argon.

The first substrate 100 and the second substrate 500 are bonded together on the bonding surface. In the present embodiment, the silicon layer 300 and the second layer 400 are bonded together. The bonding stage may be performed at a room temperature.

As described above, the composite wafer 10 is manufactured. In this case, high joining strength can be obtained by performing the heat treatment of a low temperature. In addition to or instead of providing the silicon layer 300 in the first layer 200, the silicon layer 300 may be provided in the second layer 400. In addition, one of the first substrate 100 or the second substrate 500 may be ion-implanted in advance.

### Example 1

A wafer obtained by forming a film of SiO₂ on an LT wafer and polishing the film was prepared. On the other side, a silicon wafer having a thermal oxide film formed was prepared. Two types of silicon wafers were prepared: a silicon wafer having an amorphous silicon film of about 10 nm formed on the thermal oxide film by the PVD method; and a silicon wafer not having the amorphous silicon film. Plasma activation was performed in a nitrogen atmosphere for 30 seconds, and after bonding, heat treatment of 100° C. was performed for 24 hours. Thus, a composite wafer was obtained. There was no peeling or the like in the case where the amorphous silicon film was formed, but peeling or cracks were observed in the periphery in the case where the amorphous silicon film was not formed.

### Example 2

A wafer obtained by forming a film of SiO₂ on an LT wafer and polishing the film was prepared. On the other side, a silicon wafer having a thermal oxide film formed was prepared. Two types of LT wafers were prepared: an LT wafer having an amorphous silicon film of about 10 nm formed on the oxide film by the PVD method; and an LT wafer not having the amorphous silicon film. Plasma activation was performed in a nitrogen atmosphere for 30 seconds, and after bonding, heat treatment of 100° C. was performed for 24 hours. There was no peeling or the like in the case where the amorphous silicon film was formed, but peeling or cracks were observed in the periphery in the case where the amorphous silicon film was not formed.

### Example 3

A wafer obtained by forming a film of SiON on an LT wafer and polishing the film was prepared. On the other side, a silicon wafer having a thermal oxide film formed was prepared. Two types of silicon wafers were prepared: a silicon wafer having an amorphous silicon film of about 10 nm formed on the thermal oxide film by the PVD method; and a silicon wafer not having the amorphous silicon film. Plasma activation was performed in a nitrogen atmosphere for 30 seconds, and after bonding, heat treatment of 100° C. was performed for 24 hours. There was no peeling or the like in the case where the amorphous silicon film was formed, but peeling or cracks were observed in the periphery in the case where the amorphous silicon film was not formed.

### Example 4

A wafer obtained by forming a film of SiN on an LT wafer and polishing the film was prepared. On the other side, a silicon wafer having a thermal oxide film formed was prepared. Two types of silicon wafers were prepared: a silicon wafer having an amorphous silicon film of about 10 nm formed on the thermal oxide film by the PVD method; and a silicon wafer not having the amorphous silicon film. Plasma activation was performed in a nitrogen atmosphere for 30 seconds, and after bonding, heat treatment of 100° C. was performed for 24 hours. There was no peeling or the like in the case where the amorphous silicon film was formed, but peeling or cracks were observed in the periphery in the case where the amorphous silicon film was not formed.

### Example 5

The LT wafer in Examples 1 to 4 was changed to LN, alumina (sapphire), and glass, and the experiment was similarly conducted, but the results were exactly the same as those in Examples 1 to 4.

### Example 6

The atmosphere for plasma activation in Examples 1 to 5 was changed to oxygen, a gas mixture of oxygen and nitrogen, and argon, and a similar experiment was conducted, but the results were the same.

### Example 7

The amorphous silicon film of about 10 nm in Examples 1 to 6 was formed by the CVD method and used to conduct a similar experiment, but the results were the same.

### Example 8

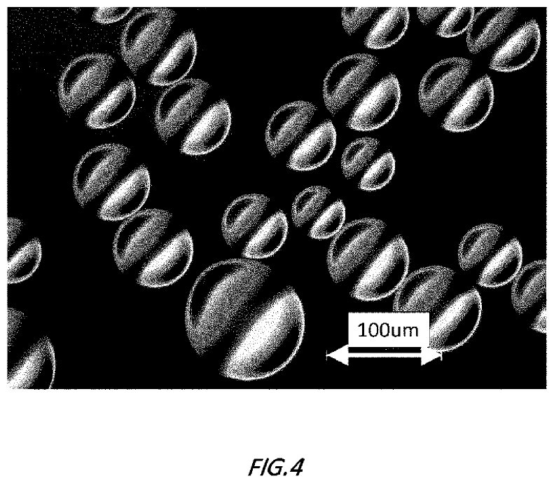

An experiment was conducted with the thickness of the amorphous silicon in Examples 1 to 7 increased. The same result was obtained up to a thickness of 250 nm, but when the thickness was 275 nm, minute peeling was observed on the entire surface of the wafer by using an optical microscope. As an example, an optical microscope image of glass (transparent) and LT bonded with amorphous silicon of 160 nm interposed therebetween is illustrated in FIG. 4. This is considered to be because impurities (such as hydrogen) taken into the amorphous silicon by the PVD method or the CVD method were volatilized, and those that could not be absorbed induced peeling. Therefore, it can be said that the thickness of the amorphous silicon is desirably 150 nm or less.

### Example 9

One of the wafers to be bonded was ion-implanted with hydrogen in advance, but the result was the same as those of Examples 1 to 8. These wafers were bonded together and then subjected to ion implantation peeling after the heat treatment, thereby obtaining a composite wafer in which thin films were laminated.

### Example 10

Only one wafer, not both wafers, was subjected to the plasma activation in Examples 1 to 9. The result was the same as those in Examples 1 to 9, regardless of which wafer was subjected to the plasma activation.

### Example 11

A wafer obtained by forming a film of SiO₂ on an LT wafer implanted with hydrogen ions in advance and polishing the film was prepared. On the other side, a silicon wafer having a thermal oxide film formed was prepared. In the silicon wafer, on the thermal oxide film was formed an amorphous silicon film of about 5 nm by the PVD method, and on the LT wafer on which the film of SiO₂ was formed was also formed an amorphous silicon film of about 5 nm. This wafer was bonded by a room-temperature joining method by using an argon beam under high vacuum. The bonded wafer was peeled off at the ion implantation interface, and heat treatment of 450° C. was performed in order to recover the crystallinity disturbed by the ion implantation, but peeling occurred in a part of the wafer.

A cross section of the wafer was observed with a transmission electron microscope (TEM), the amorphous silicon was observed by energy dispersive X-ray analysis (EDX), and as a result, a high concentration of argon (1.5% or more) was observed. On the other hand, the sample obtained in Example 9 was similarly subjected to the heat treatment of 450° C., and a similar observation was conducted, but argon was not observed.

In addition, metal contamination of the silicon wafer irradiated with the argon beam used for the room-temperature joining was observed by an ICP-MS method, and iron, chromium, nickel, or the like was observed to have a high concentration of 1.0e11 atoms/cm 2 or more. It can be said that it is essentially difficult to escape from the metal contamination in the room-temperature joining. On the other hand, a high concentration of contamination was not observed from the silicon wafer subjected to plasma activation, and the degree of contamination for the metal was 5.0e10 atoms/cm 2 or less.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

100: first substrate;
200: first layer;
300: silicon layer;
400: second layer; and
500: second substrate.

What is claimed is:

1. A composite wafer comprising:
a first substrate in which a first layer of any one of oxides, oxynitrides, and nitrides is disposed on one surface;
a second substrate in which a second layer of any one of oxides, oxynitrides, and nitrides is disposed on one surface; and
a silicon layer which is disposed between the first layer and the second layer.

2. The composite wafer according to claim 1, wherein the silicon layer is amorphous silicon.

3. The composite wafer according to claim 1, wherein the silicon layer is 2 nm or more and 250 nm or less.

4. The composite wafer according to claim 2, wherein the silicon layer is 2 nm or more and 250 nm or less.

5. The composite wafer according to claim 3, wherein the silicon layer has an argon concentration of 1.5% atomic or less.

6. The composite wafer according to claim 3, wherein the silicon layer has a surface concentration of iron, chromium, and nickel of 5.0e10 atoms/cm′ or less.

7. The composite wafer according to claim 5, wherein the silicon layer has a surface concentration of iron, chromium, and nickel of 5.0e10 atoms/cm 2 or less.

8. The composite wafer according to claim 1, wherein each of the first substrate and the second substrate is any one of silicon, glass, alumina, sapphire, lithium tantalate, and lithium niobate.

9. The composite wafer according to claim 2, wherein each of the first substrate and the second substrate is any one of silicon, glass, alumina, sapphire, lithium tantalate, and lithium niobate.

10. The composite wafer according to claim 8, wherein at least one of the first layer or the second layer is any one of SiO₂, SiON, and SiN.

11. A manufacturing method for a composite wafer comprising:
preparing a first substrate in which a first layer of any one of oxides, oxynitrides, and nitrides is disposed on one surface;
preparing a second substrate in which a second layer of any one of oxides, oxynitrides, and nitrides is disposed on one surface;
forming a silicon layer on a surface of one of the first layer or the second layer;
activating, with plasma, a surface of at least one of the silicon layer or another of the first layer or the second layer; and
bonding the first substrate and the second substrate.

12. The manufacturing method for the composite wafer according to claim 11, wherein the silicon layer is amorphous silicon.

13. The manufacturing method for the composite wafer according to claim 12, wherein in the forming, the silicon layer is formed by PVD or CVD.

14. The manufacturing method for the composite wafer according to claim 11, wherein the silicon layer is 2 nm or more and 250 nm or less.

15. The manufacturing method for the composite wafer according to claim 14, wherein the silicon layer has an argon concentration of 1.5% atomic or less.

16. The manufacturing method for the composite wafer according to claim 14, wherein the silicon layer has a surface concentration of iron, chromium, and nickel of 5.0e10 atoms/cm 2 or less before or after the bonding.

17. The manufacturing method for the composite wafer according to claim 11, wherein each of the first substrate and the second substrate is any one of silicon, glass, alumina, sapphire, lithium tantalate, and lithium niobate.

18. The manufacturing method for the composite wafer according to claim 17, wherein at least one of the first layer or the second layer is any one of SiO₂, SiON, and SiN.

19. The manufacturing method for the composite wafer according to claim 11, wherein one of the first substrate or the second substrate is ion-implanted in advance.

20. The manufacturing method for the composite wafer according to claim 11, wherein an atmosphere of activation with plasma contains at least one of nitrogen, oxygen, a gas mixture of oxygen and nitrogen, or argon.
